(19) United States
(12) Patent Application Publication
(10) Pub. No.: US 2012/0175656 A1
(43) Pub. Date: Jul. 12, 2012

(54) LIGHT EMITTING DIODE PACKAGE

(75) Inventors: JUNG-HSI FANG, Hukou (TW); SHIH-YUAN HSU, Hukou (TW)

(73) Assignee: ADVANCED OPTOELECTRONIC TECHNOLOGY, INC., Hsinchu Hsien (TW)

(21) Appl. No.: 13/287,224

(22) Filed: Nov. 2, 2011

(30) Foreign Application Priority Data
Jan. 11, 2011 (CN) 201110003969.0

(51) Int. Cl. H01L 33/60

(52) U.S. Cl. 257/98; 257/E33.072

(57) ABSTRACT

A light emitting diode package includes a base, a chip mounted on the base, and an encapsulant layer encapsulating the chip. The encapsulant layer includes a light exit face for light generated generated by the chip transmitting through. A plurality of microstructures are formed on the light exit face. Distribution of the microstructures has the following characters: a density of the microstructures is inversely proportional to a light intensity of the light at the light exit face; and a size of the microstructures is inversely proportional to the light intensity of the light at the light exit face.

### BACKGROUND

1. Technical Field

The present disclosure generally relates to a light emitting diode (LED) package.

2. Description of Related Art

Light emitting diodes (LEDs) as a new type of light source may generate brighter light than conventional light sources, and may have many advantages, such as energy saving, environment friendliness, and a long life-span. The LED generally includes an LED chip and a transparent encapsulant layer encapsulating the LED chip. Since a refractive index of the encapsulant layer is larger than that of the air, when an incidence angle of incident light of the LED chip is larger than a critical angle, total reflection of the incident light will occur at an interface between the encapsulant layer and the air, under which condition light cannot radiate out of the encapsulant layer. Moreover, distribution of light emitted from the LED chip may be uneven. A larger angle between the incident light and a central axis of the LED chip will result in a lesser luminous intensity.

What is needed, therefore, is an LED package which may overcome the shortcomings as described.

### BRIEF DESCRIPTION OF THE DRAWINGS

FIG. 1 is a cross-sectional view of an LED package in accordance with a first embodiment of the disclosure.

FIG. 2 is a cross-sectional view of an LED package in accordance with a second embodiment of the disclosure.

### DETAILED DESCRIPTION

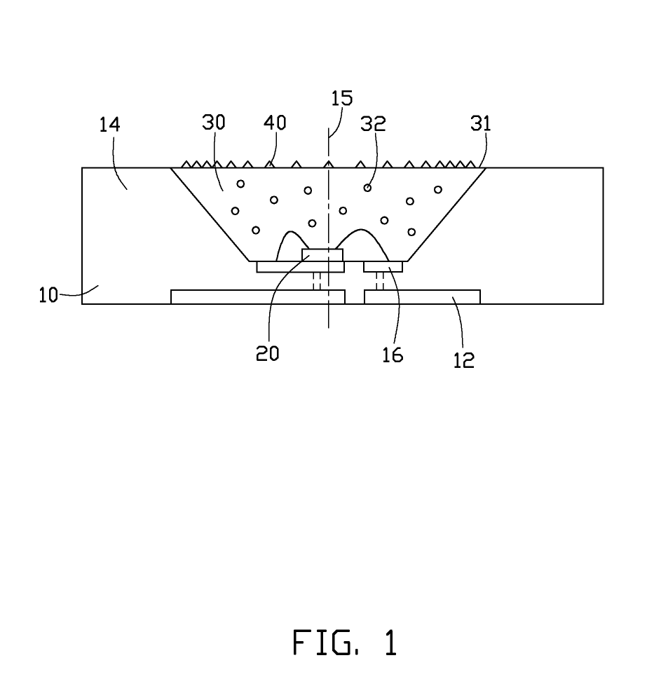

Referring to FIG. 1, wherein a first embodiment of an LED package in accordance with the present disclosure is shown. The LED package includes a substrate 10, an LED chip 20 attached to the substrate 10, a reflective cup 14 encircling the LED chip 20, and an encapsulant layer 30 filled in the reflective cup 14 and encapsulating the LED chip 20.

In the embodiment shown in FIG. 1, the substrate 10 is a flat plate. A circuit structure is formed on the substrate 10. The circuit structure includes two internal electrodes 16 formed on a top face of the substrate 10, and two external electrodes 12 formed on a bottom face of the substrate 10. Each of the two internal electrodes 16 is electrically connected to each of the two external electrodes 12.

The LED chip 20 is disposed on one of the two internal electrodes 12, and electrically connected to each of the two internal electrodes 12 by a lead wire. The LED chip 20 has an optical axis 15 perpendicular to the substrate 10. The more is an angle between the light and the optical axis 15 of the LED chip 20, the less is the luminous intensity.

The reflective cup 14 is annular with a chamber extending therethrough. A bottom of the reflective cup 14 is attached to the top side of the substrate 10. An inner surface of the reflective cup 14 defining the chamber surrounds the LED chip 20. The inner surface reflects light emitted from the LED chip 20. A central axis of the reflective cup 14 is collinear with the optical axial 15 of the LED chip 20. The reflective cup 14 may be made of a same material as the substrate 10. In the embodiment of FIG. 1, the reflective cup 14 and the substrate 10 are integrally made as one piece. Alternatively, the reflective cup 14 and the substrate 10 may be separately formed and then assembled integrally.

The encapsulant layer 30 is received in the chamber of the reflective cup 14. Light generated from the LED chip 20 may transmit through the encapsulant layer 30 to outside. A light exit face 31 of the encapsulant layer 30 for emitting the light to the outside is coplanar with a top face of the reflective cup 14. A plurality of fluorescent powders 32 are contained in the encapsulant layer 30, for diffusing the light from the LED chip 20.

A plurality of microstructures 40 are formed on the light exit face 31 of the encapsulant layer 30. Light generated from the LED chip 20 may be transmitted through the plurality of microstructures 40. Each of the plurality of microstructure 40 is a cone-shaped protrusion. Densities of the plurality of microstructures 40 are inversely proportional to light intensities at the light exit face 31. In other words, a first area of the light exit face 31 with a low light intensity corresponds to a high density of the plurality of microstructures 40; whereas a second area of the light exit face 31 with a high light intensity corresponds to a small density of the plurality of microstructures 40. In another words, the longer are the distances between the plurality of microstructures 40 and the optical axis 15, the higher is the density of the plurality of microstructures 40; whereas the shorter are the distances between the plurality of microstructures 40 and the optical axis 15, the lower is the density of the plurality of microstructures 40.

Since there are more plurality of microstructures 40 in an area away from the optical axis 15 on the light exit face 31, more light will be refracted by the plurality of microstructures 40 in the area. Light of total reflection may not easily occur in the area away from the optical axis 15 on the light exit face 31. Thus, light emitted from the LED package, as a whole, may be more evenly distributed, according to the embodiment.

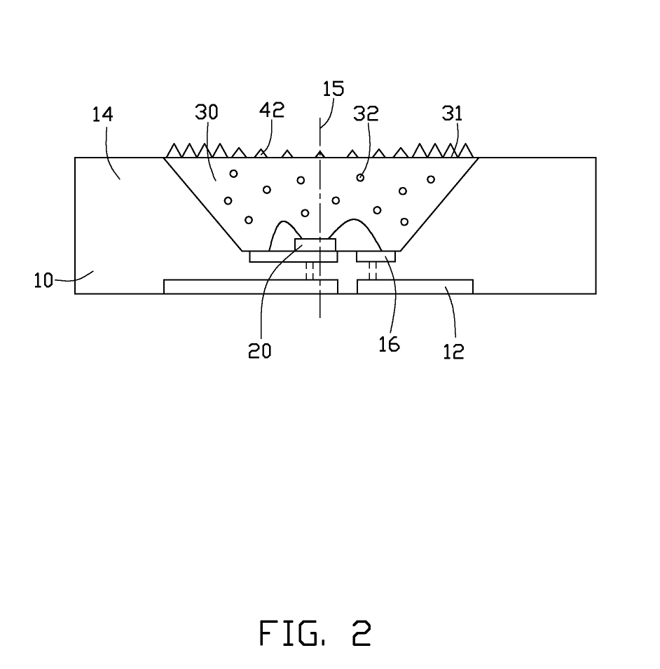

Also referring to FIG. 2, wherein a second embodiment of an LED package in accordance with the present disclosure is shown. The second embodiment of the LED package is similar to the first embodiment of the LED package. In addition to all elements shown in FIG. 2, the second embodiment comprises a plurality of microstructures 42 formed on the light exit face 31 of the encapsulant layer 30. Each of the plurality of microstructure 42 is a cone-shaped protrusion. A density of the plurality of microstructures 42 is inversely proportional to a light intensity at the light exit face 31. An additional character of the second embodiment of the LED package is that sizes of the plurality of microstructures 42 are inversely proportional to the light intensity at the light exit face 31. That is to say, the longer are the distances between the plurality of microstructures 42 and the optical axis 15, the larger are the sizes of the plurality of microstructures 42; whereas the shorter are the distances between the plurality of microstructures 42 and the optical axis 15, the smaller are the sizes of the plurality of microstructures 42.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package comprising:
an LED chip for generating light;
an encapsulant layer encapsulating the LED chip, the encapsulant layer comprising a light exit face for light of the LED chip transmitting through to outside; and
a plurality of microstructures formed on the light exit face, the plurality of microstructures having a density, wherein the density of the plurality of microstructures is inversely proportional to a light intensity of the light generated by the LED chip at the light exit face.

2. The LED package of claim 1, further comprising an annular reflective cup; the encapsulant layer and the LED chip are received in the annular reflective cup.

3. The LED package of claim 1, the plurality of microstructures having a size; wherein the size of the plurality of microstructures is proportional to the light intensity of the light generated by the LED chip at the light exit face.

4. The LED package of claim 1, further comprising a substrate, and a circuit structure; wherein the circuit structure is formed on the substrate, and the LED chip is electrically connected to the circuit structure.

5. The LED package of claim 4, wherein the LED chip is disposed on the circuit structure.

6. The LED package of claim 4, wherein the circuit structure extends from a top face to a bottom face of the substrate.

7. The LED package of claim 4, the LED package further comprises fluorescent powders; the fluorescent powders are contained in the encapsulant layer.

8. The LED package of claim 1, wherein each of the plurality of microstructures is a cone-shaped protrusion.

9. A light emitting diode (LED) package comprising:
an LED chip having an optical axis;
an encapsulant layer encapsulating the LED chip, the encapsulant layer having a light exit face for transmitting light generated from the LED chip out of the LED package, the optical axis of the LED chip extending through the light exit face; and
a plurality of microstructures formed on the light exit face, wherein the plurality of microstructures having the following characters: the longer a distance between the plurality of microstructures and the optical axis, the higher the density of the plurality of microstructures; the longer the distance between the plurality of microstructures and the optical axis, the larger the size of the plurality of microstructures.

10. The LED package of claim 9, further comprising an annular reflective cup; the annular reflective cup is located on a substrate, and the encapsulant layer and the LED chip are received in the annular reflective cup.

11. The LED package of claim 9, further comprising a circuit structure; the circuit structure is attached to the substrate, and the LED chip is electrically connected to the circuit structure.

12. The LED package of claim 11, wherein the LED chip is disposed on the circuit structure.

13. The LED package of claim 11, wherein the circuit structure extends from a top face to a bottom face of the substrate.

14. The LED package of claim 9, wherein light generated from the LED chip is refracted by the plurality of microstructures.

15. The LED package of claim 9, wherein each of the plurality of microstructure is a cone-shaped protrusion.
